(19) United States
(12) Patent Application Publication
(10) Pub. No.: US 2009/0309181 A1
(43) Pub. Date: Dec. 17, 2009

(54) TRENCH SCHOTTKY WITH MULTIPLE EPI STRUCTURE

(75) Inventor: Fu-Yuan Hsieh, HsinChu (TW)

Correspondence Address: BAYSHORE PATENT GROUP, LLC, 520 CHANTECLER DR., FREMONT, CA, 94539, US

(73) Assignee: FORCE MOS TECHNOLOGY CO. LTD., HsinChu (TW)

(21) Appl. No.: 12/137,550

(22) Filed: Jun. 12, 2008

(51) Int. Cl. H01L 29/47

(52) U.S. Cl. 257/471; 257/E29.148

(57) ABSTRACT

A trench Schottky barrier rectifier includes an cathode electrode at a face of a semiconductor substrate and an multiple epitaxial structure in drift region which in combination provide high blocking voltage capability with low reverse-biased leakage current and low forward voltage. The multiple structure of the drift region contains a concentration of first conductivity dopants therein which comprises two or three different uniform value from a Schottky rectifying junction formed between the anode electrode and the drift region. The thickness of the insulating region (e.g., SiO2) in the MOS-filled trenches is greater than 1000 Å to simultaneously inhibit field crowing and increase the breakdown voltage of the device. The multiple epi structure is preferably formed by epitaxial growth from the cathode region and doped in-situ.

### FIELD OF THE INVENTION

This invention relates generally to the cell structure, device configuration and fabrication process of rectifiers. More particularly, this invention relates to novel and improved metal-semiconductor rectifying devices with a higher breakdown voltage, a lower forward voltage drop and lower reverse leakage characteristics and the methods of forming these devices with such characteristics.

### BACKGROUND

Schottky barrier rectifiers are used extensively as output rectifiers in switching-mode power supplies and in other high-speed power switching applications, such as motor drivers, for carrying large forward currents and supporting reverse blocking voltage of up to 100 Volts. Schottky barrier rectifiers are also applicable to a wide range of other applications such as those illustrated in FIG. 1. As is well known to those having skill in the art, rectifiers exhibit low resistance to current flow in a forward direction and a very high resistance to current flow in a reverse direction. As is also well known to those having skill in the art, a Schottky barrier rectifier produces rectification as a result of nonlinear unipolar current transport across a metal-semiconductor contact.

As the voltage of modern power supplies continue to decrease in response to need for reduced power consumption and increased energy efficiency, it becomes more advantageous to decrease the on-state voltage drop across a power rectifier, while still maintaining high forward-biased current density levels. As well known to those skilled in the art, the on-state voltage drop is generally dependent on the forward voltage drop across the metal/semiconductor junction and the series resistance of the semiconductor region and cathode contact.

In U.S. Pat. No. 5,612,567, a Schottky rectifier and the method of forming the same are disclosed to provide high blocking voltage capability with low reverse-biased leakage current and low forward voltage drop. The Schottky rectifier has insulator-filled trenches and an anode electrode thereon at a face of a semiconductor substrate and an optimally non-uniformly doped doped drift region. As shown in FIG. 2, the rectifier 10 includes a semiconductor substrate 12 of first conductivity type, typically N-type conductivity, having a first face 12a and a second opposing face 12b. The substrate 12 preferably comprises a relatively highly doped cathode region 12c (shown as N+) adjacent the first face 12a. As illustrated, the cathode region 12c is doped to a uniform first conductivity type dopant concentration of about 1×10¹⁹ cm⁻³. An optimally non-uniformly doped drift region 12d of first conductivity type (shown as N) preferably extends from the cathode region 12c to the second face 12b which is rectifying region (Shottky barrier region). As illustrated, the drift region 12d and cathode region 12c form a non-rectifying N+/N junction which extends opposite the first face 12a. A mesa 14 having a cross-sectional width “Wm”, defined by opposing sides 14a and 14b, is preferably formed in the drift region 12d. Alternatively, an annular-shaped trench may also be formed in the drift region 12d to define the mesa 14. An insulating region 16 is also provided on the opposing mesa sides 14a and 14b, respectively. The rectifier also includes an anode electrode 18 on the insulating region 16 and on the second face 12b. The anode electrode 18 forms a Schottky barrier rectifying junction with the drift region 12d at the top face of the mesa 14. The height of the Schottky barrier formed at the anode electrode/mesa interface is dependent on the type of electrode metal and semiconductor used and the magnitude and profile of the first conductivity type doping concentration in the mesa 14. Finally, a cathode electrode 20 is provided adjacent the cathode region 12c at the first face 12a, The cathode electrode 20 preferably ohmically contacts the cathode region 12c.

In particular, the concentration of first conductivity type dopants in the interface of drift region 12d and 12C is most preferably about 3×10¹⁷ cm⁻³ at the non-rectifying junction, as also illustrated best by FIG. 3, the profile of the first conductivity type dopant concentration in the drift region 12d is preferably a linear graded profile.

Considering the doping concentration of the drift region, which is linearly increased from the second face to the interface of 12d and 12c, the concentration near the bottom of the trench is higher than other portion, resulting in early breakdown near the bottom of the trench when reverse-biased is applied.

Another limitation of the Schottky rectifier in the prior art is the implement of the linearly gradient doping epitaxial layer discussed above, which is not feasible for mass production because the gradient of doping concentration is not easily controlled and monitored.

Therefore, there is still a need in the art of the Schottky rectifier design and fabrication, to provide a novel rectifier structure and fabrication process that would resolves these difficulties and design limitation.

### SUMMARY OF THE INVENTION

It is therefore an aspect of the present invention to provide new and improved configuration and manufacture processes for Schottky rectifier with reduced forward voltage drop and reduced reverse leakage current while maintaining targeted breakdown voltage. And what is more important is the improved method should be feasible for mass production.

Briefly, in a preferred embodiment, the present invention discloses a Schottky barrier rectifier with double epitaxial layer with lower doping concentration near trench bottom and higher doping concentration above the trench bottom. The upper epitaxial layer doping concentration can be monitored by Hg-CV method while the lower epi layer doping concentration is able to be calculated by measuring total doping concentration of two epitaxial layers using 4PP (Four Point Probe) method, and then subtracting the upper doping concentration measured by Hg-CV method. The substrate comprises a highly doped N+ region, on which epitaxial layer is grown. In the prior art, the concentration of the epitaxial layer is linearly increased from the second face to the interface of the epitaxial layer and N+ region, which results in some problems as we discussed above. In the present invention, the epitaxial layer is designed to comprise two values of concentrations. The concentration remains the same from the second face to the bottom of the trench and from the bottom of the trench to the interface of the epitaxial layer and the N+ region, respectively. Meanwhile, the former concentration is higher than the latter one. This double epi design has the advantage of maintaining targeted BV near trench bottom due to the lower doping concentration, while forward voltage drop is reduced with higher doping concentration in drift region between trenches. In another embodiment, an improvement is designed on base of the first embodiment. Near the surface of the epitaxial layer, shallow boron or BF 2 Ion Implantation is introduced to reduce the reverse leakage current between anode and cathode. As the concentration is lower near the surface of the epitaxial layer, the Schottky barrier height is increased, thus leading to the reduction of reverse leakage current between anode and cathode. Besides this, the concentration is the same from the shallow implanted layer to the bottom of the trench and from the bottom of the trench to the interface of the epitaxial layer and the N+ region, respectively, which maintain the advantages of the first embodiment. In another embodiment, there is a triple epitaxial layers in the rectifier. A thin epitaxial layer near the surface of the epitaxial layer is uniformly doped with a low concentration. From the thin layer to the bottom of the trench, the concentration is higher than the above thin layer and also is uniform as the former two embodiments. From the bottom of the trench to the interface of the epitaxial layer to the N+ region, the concentration is lower again and the same as the concentration of the thin layer. This triple epitaxial layers design has the advantages of that of both two embodiments discussed above. And in all three embodiments, the oxide layer around the trench is greater than about 1000 Å, and that will contribute to an increase in the reverse breakdown voltage.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The present invention can be more fully understood by reading the following detailed description of the preferred embodiments, with reference made to the accompanying drawings, wherein:

FIG. 1 illustrates typical applications of power semiconductor devices as a function of device current rating and device blocking voltage rating.

FIG. 2 is a cross sectional view of Schottky rectifier of the prior art.

FIG. 3 is a cross sectional representation of the prior art, and the profile on the right illustrates the doping concentration in the epitaxial layer and cathode region of the Schottky rectifier on the left, as a function of distance.

FIG. 4 is a cross sectional view of Schottky rectifier according to the first embodiment of this invention, and the profile on the right illustrates the doping concentration in the epitaxial layer and cathode region of the Schottky rectifier on the left, as a function of distance.

FIG. 5 is a cross sectional view of Schottky rectifier according to the second embodiment of this invention, and the profile on the right illustrates the doping concentration in the epitaxial layer and cathode region of the Schottky rectifier on the left, as a function of distance.

FIG. 6 is a cross sectional view of Schottky rectifier according to the third embodiment of the invention, and the profile on the right illustrates the doping concentration in the epitaxial layer and cathode region of the Schottky rectifier on the left, as a function of distance.

FIGS. 7A to 7E are a serial of side cross sectional views for showing the processing steps for fabricating a trench Schottky rectifier as shown in FIG. 5.

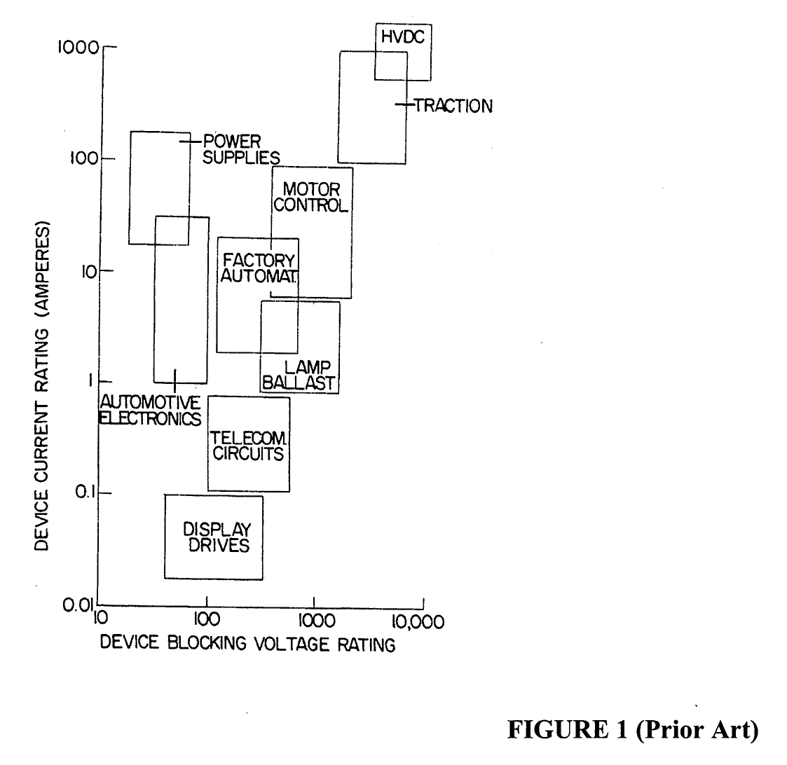

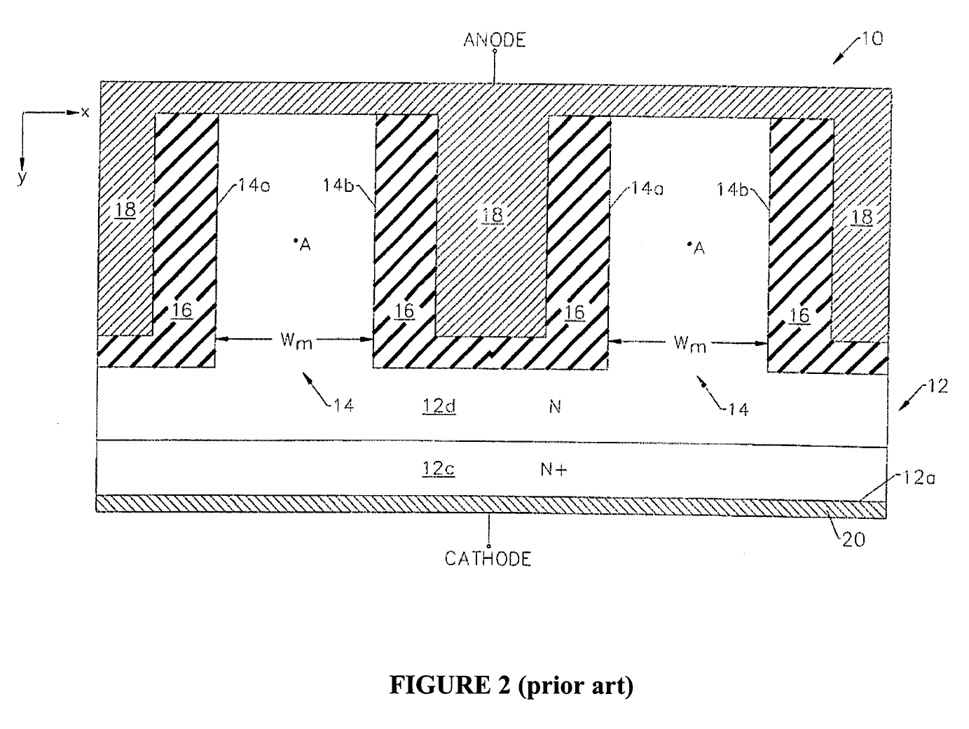

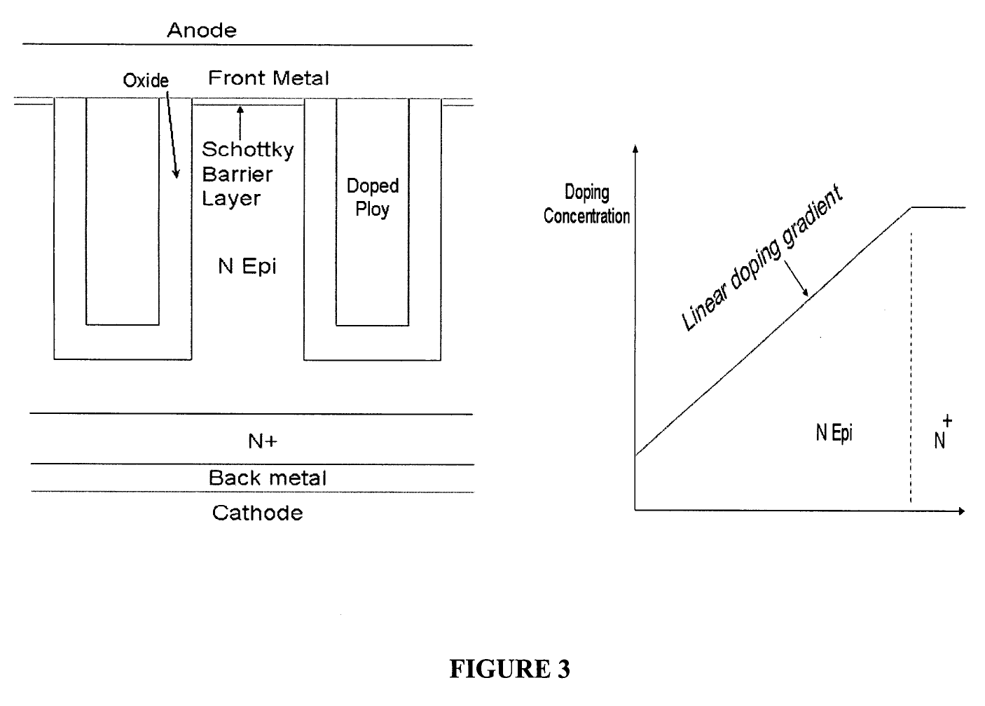

### DETAILED DESCRIPTION OF THE EMBODIMENTS

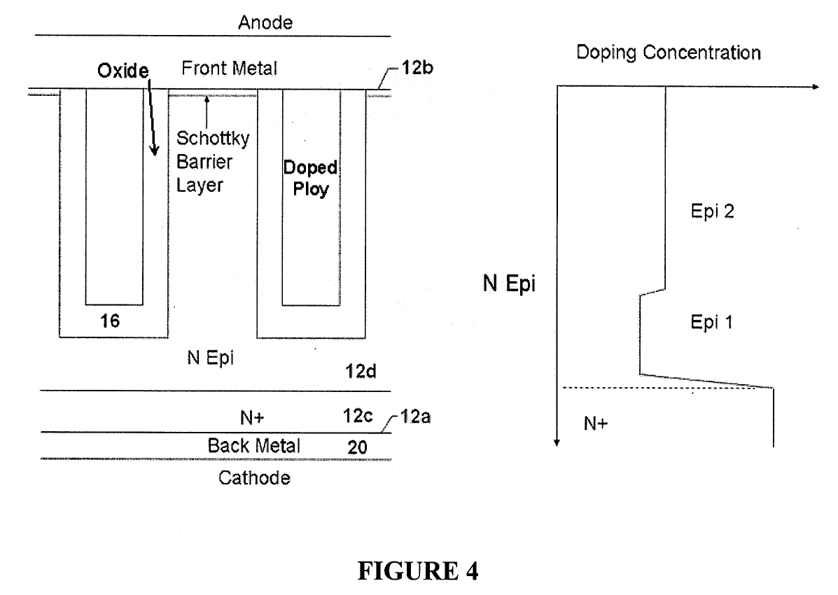

Please refer to FIG. 4 to FIG. 6 for preferred embodiments of this invention. In FIG. 4, a rectifier 11 comprises a semiconductor substrate 12 including a highly doped N+ region 12c and an epitaxial layer 12d formed on it. The highly doped N+ region 12c serves as the cathode region with a layer of back metal formed beneath it. The lower doped epitaxial layer 12d has a first face 12a adjacent the N+ region and a second face 12b opposing the face 12a. As illustrated, the epitaxial layer 12d and cathode region 12c form a non-rectifying N+/N junction which extends opposite the first face 12a. An insulating layer 16 (e.g., SiO2) is provided around the trenches 13 formed in the drift region 12d. To facilitate achievement of a high breakdown voltage and inhibit field crowding, the insulating region 16 is formed to have a thickness greater than 1000 Å. The rectifier also includes an anode metal layer 14 on the insulating layer 16 and on the second face 12b. The anode metal layer forms a Schottky barrier rectifying junction 17 with the drift region 12d at the top face between the trenches. The height of the Schottky barrier formed is dependent on the type of electrode metal and semiconductor used and the magnitude and the profile of the first conductivity type doping concentration of the drift region 12d between the trenches. As illustrated in the profile in FIG. 4, in this invention, the concentration remains the same from the second face 12b to the bottom of the trench and from the bottom of the trench to the first face 12a, respectively. At the same time, the former concentration is designed to higher than the latter one. The lower concentration near the bottom of the trench solves the problem of early breakdown occurring and maintain targeted BV near trench bottom while reducing forward voltage drop with higher doping concentration in drift region between trenches.

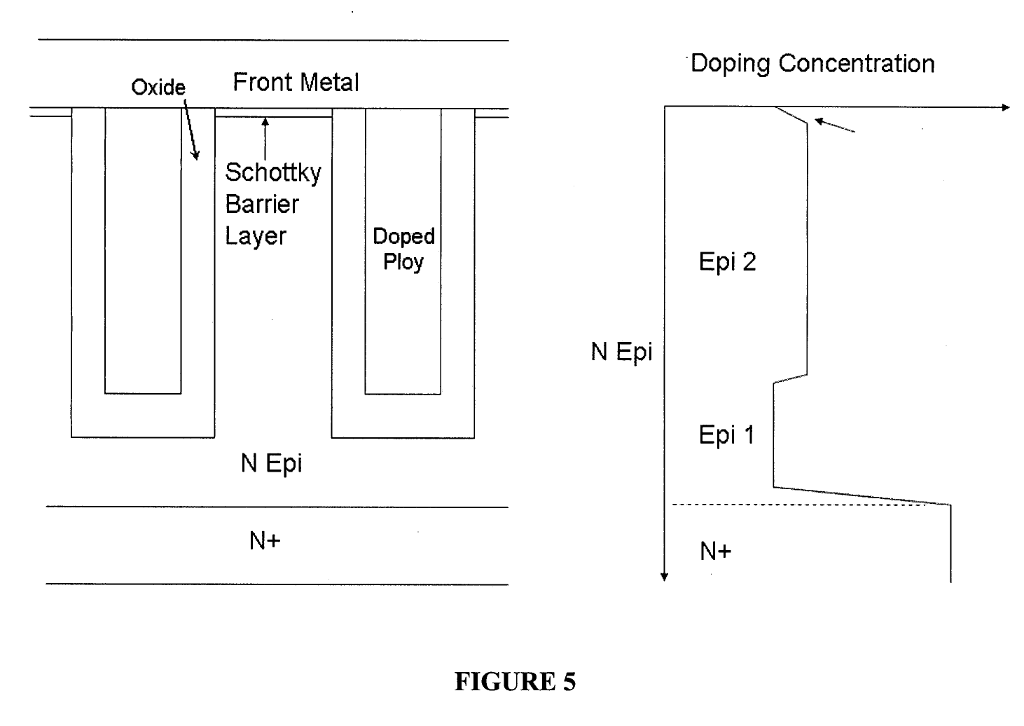

Referring to FIG. 5 for the second preferred embodiment, the rectifier of this embodiment has the same structure with the first one but for the concentration distribution of the drift region 12d. As illustrated in the profile on the right of FIG. 5. The profile also shows a double epitaxial concentration distribution, but near the surface of the drift region 12d, shallow Boron or BF 2 Ion Implantation is introduced to increase the height of the Schottky barrier, thus reducing the reverse leakage current between anode and cathode. As shown in the profile, the concentration of upper portion is higher than the lower portion, which is benefit to maintain targeted BV near trench bottom while reducing the forward voltage drop.

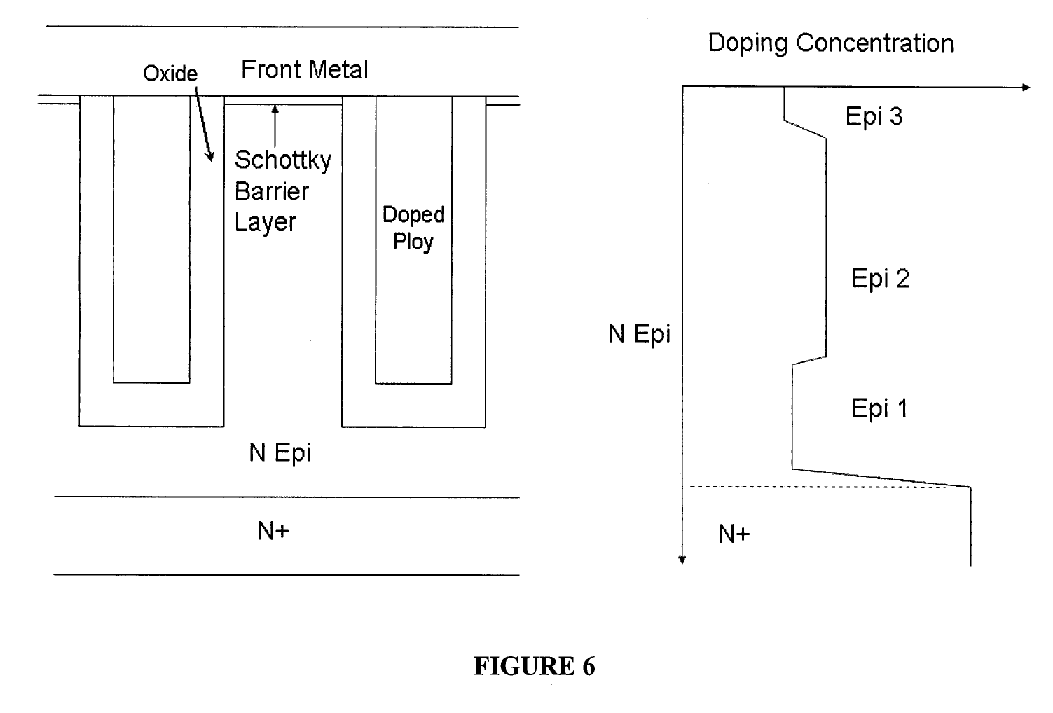

Please refer to FIG. 6 for the third embodiment of this invention, still the same structure of the rectifier, the concentration comprises three values of distribution. As shown in the profile of FIG. 6. Instead of the shallow Boron or BF 2 Ion Implantation, a thin layer near the surface of drift region 12d is uniformly doped with a low concentration. From the thin layer to the bottom of the trench and from the bottom of the trench to the first face 12a, the concentration remains the same, respectively, as discussed in the above two embodiments. In the triple epitaxial model, as shown is the profile, the concentration of the middle portion is the higher than the other two portions. This kind of distribution keeps the advantages of above two embodiments, which are reducing the reverse leakage current due to higher barrier height, and reducing forward voltage drop with higher doping concentration in drift region between trenches, and maintaining targeted BV near trench bottom with lower doping concentration.

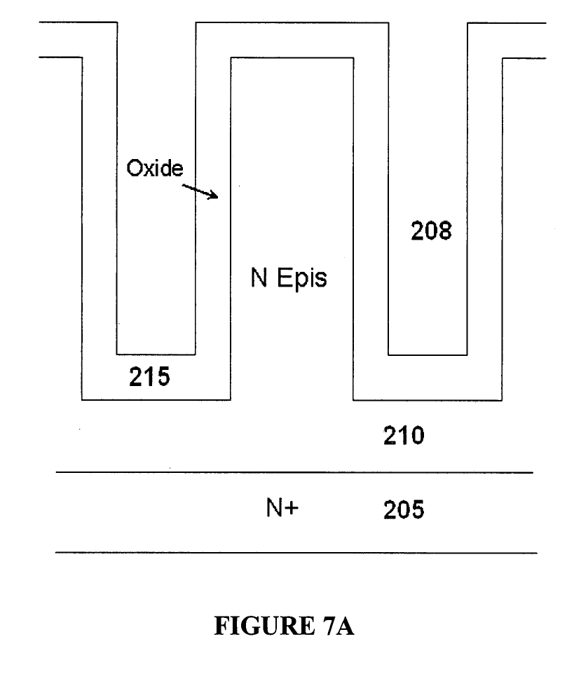

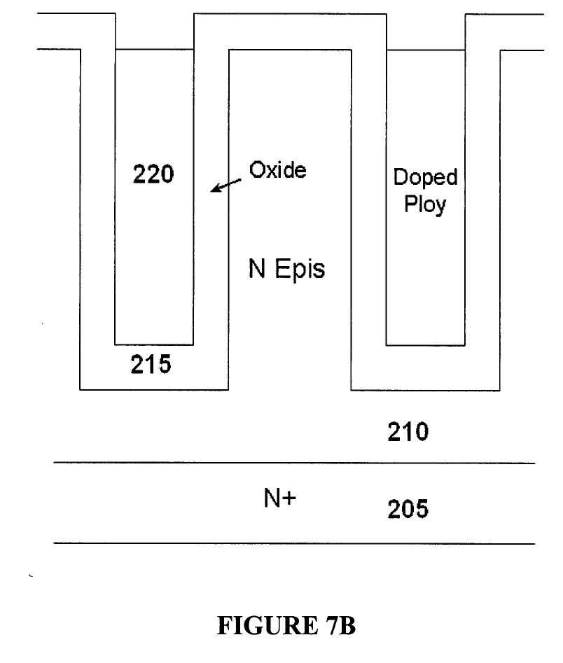

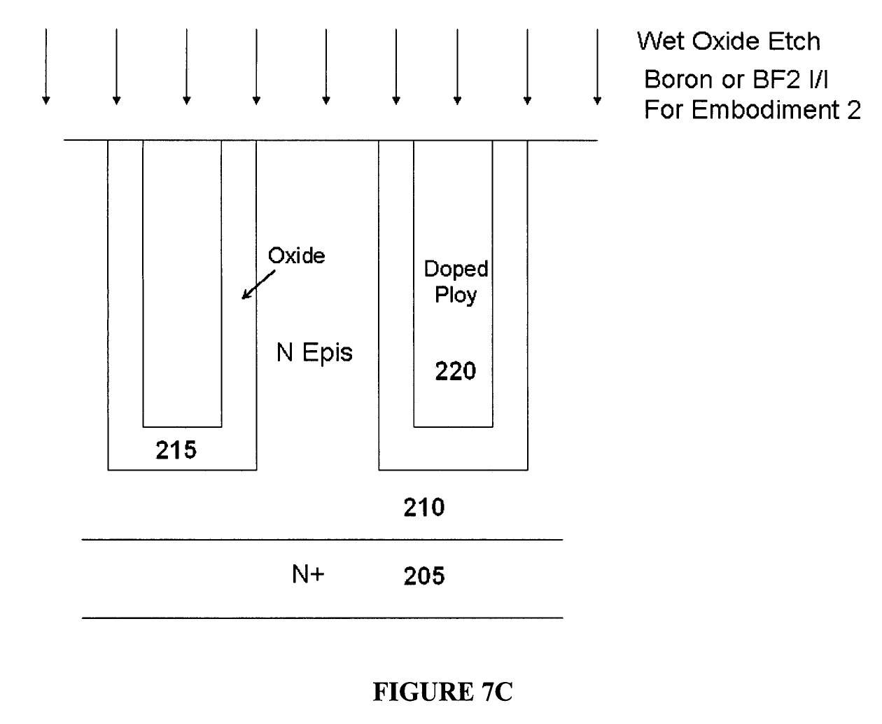

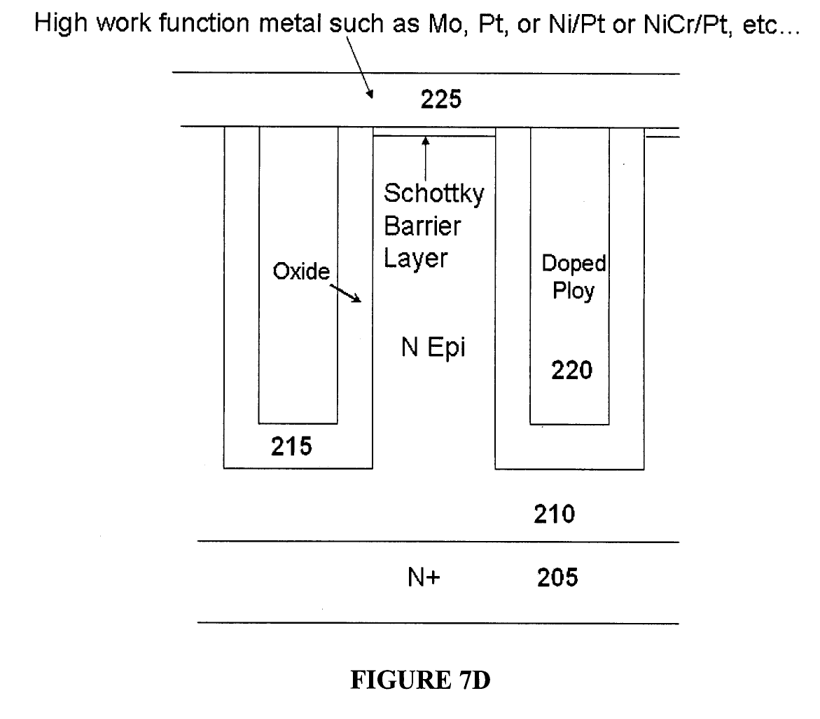

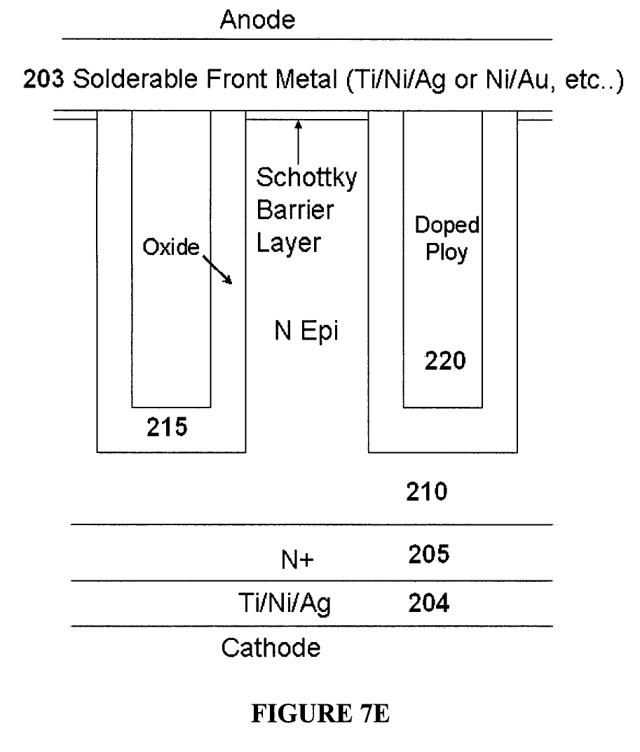

Referring to FIGS. 7A to 7E for a serial of side cross sectional views to illustrate the fabrication steps of a Schottky barrier rectifier shown in FIG. 5. In FIG. 7A, a trench mask (not shown) is applied to open a plurality of trenches 208 in an epitaxial layer 210 supported on a cathode region 205 by employing a dry silicon etch process. An oxidation process is performed to form an oxide layer covering the trench walls. The trench is oxidized with a sacrificial oxide to remove the plasma damaged silicon layer during the process of opening the trench. Then an oxide layer 215 is grown and the thickness of the oxide layer is greater than 1000 Å. In FIG. 7B, a polysilicon layer 220 is filled in the trench and covering the top surface and then doped with an N+ dopant. The polysilicon layer 220 is etched back by applying a chemical mechanical planarization process (CMP) or dry poly etch to remove the polysilicon above the top surface.

In FIG. 7C, the process continues with the removing of oxide layer by Wet Oxide Etch. A Boron or BF 2 Ion Implantation process is followed for the second embodiment to form the shallow concentration distribution. Referring to FIG. 7D, a layer of high work function metal such as Mo, Pt, or Ni/Pt or NiCr/Pt, etc, is deposed, then an elevated temperature (500 C) is applied to form silicide. Referring to FIG. 7E, the layer of high work function metal is removed with Aqua Regia, and followed the deposition of solderable front metal 203, such as Ti/Ni/Ag or Ni/Au, ect. Beneath the cathode region 205, a layer of back metal 204 is deposed to form the cathode electrode.

Although the present invention has been described in terms of the presently preferred embodiment, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A trench Schottky rectifier with multiple epitaxial structure to achieve targeted BV, lower Vf and lower Ir, comprising:
a semiconductor substrate having first and second opposing faces for cathode and anode regions with first conductivity type, respectively;
a drift region of first conductivity type in said semiconductor substrate, said drift region extending between said the cathode (first face) and the anode (second face) and having a multiple concentration epitaxial structure in a direction from the anode to said cathode region;
a trench surrounded with an insulating layer in said drift region, said trench having a bottom and sidewall extending adjacent said drift region; and
a cathode electrode contacting said the anode region, and an anode electrode said the anode region forming a Schottky rectifying junction with said drift region.

2. The MOSFET of claim 1, wherein said multiple epi structure is double epi structure, the concentration is the same from said second face to the bottom of said trench and from the bottom of said trench to said first face, respectively.

3. The double epi structure of claim 2, wherein the top epi portion has higher doping concentration and the portion near said first face has lower concentration.

4. The double epi structure of claim 2, wherein the concentration on top epi near said second face is lower resulted by Boron or BF 2 Ion Implantation.

5. The trench MOSFET of claim 1, wherein said multiple epi structure is triple epi structure, and a thin layer near said first face is lowly doped, and the concentration from said thin layer to the bottom of the trench and from the bottom of the trench to said second face is uniform, respectively.

6. The triple epi structure of claim 5, wherein concentration of the middle portion is higher than top and bottom epi portion.

7. The trench MOSFET of claim 1, wherein said oxide thickness around trench is greater than 1000 Å
